(19) United States
(12) Patent Application Publication
(10) Pub. No.: US 2011/0108116 A1
(43) Pub. Date: May 12, 2011

(54) P-type NiO conducting film for organic solar cell, a method for preparation of NiO conducting film, and an organic solar cell with enhanced light-to-electric energy conversion using the same

(75) Inventors: Jae-Wook Kang, Gyeongsangnam-do (KR); Dong Ho Kim, Gyeongsangnam-do (KR); Sun Young Park, Gyeongsangnam-do (KR); Do-Geun Kim, Gyeongsangnam-do (KR); Jong Kuk Kim, Gyeongsangnam-do (KR)

(73) Assignee: KOREA INSTITUTE OF MACHINERY AND MATERIALS, Daejeon (KR)

(21) Appl. No.: 12/895,986

(22) Filed: Oct. 1, 2010

(30) Foreign Application Priority Data
Nov. 11, 2009 (KR) 10-2009-0108601

(51) Int. Cl. H01L 31/0256; B32B 9/00; C01G 53/04; C23C 14/34

(52) U.S. Cl. 136/263; 428/220; 423/594.19; 204/192.25

(57) ABSTRACT

A p-type NiO conducting film for an organic solar cell, a preparation method thereof, and an organic solar cell using the same and having enhanced power conversion efficiency, are provided, wherein the NiO conducting film is fabricated by vacuum sputtering in which nickel or nickel oxide is used as a target material, and argon, oxygen or the mixed gas of the argon and the oxygen is supplied. The p-type NiO conducting film may be easily prepared by vacuum sputtering, and since a n-type conducting film is prepared by simply coating sol-phase precursor solution, the NiO conducting film and the organic solar cells having the NiO conducting film in the order of the NiO conducting film, a photoactive layer, and a n-type conducting film, have enhanced electric energy conversion. As a result, the provided disclosure is useful particularly when applied in organic solar cells and organic light emitting devices.

### CROSS-REFERENCE TO RELATED APPLICATIONS

This application claims priority from Korean Patent Application No. 10-2009-0108601, filed on Nov. 11, 2009, in the Korean Intellectual Property Office, the disclosure of which is incorporated herein by reference in its entirety.

### BACKGROUND OF THE INVENTION

1. Field of the Invention

The invention relates to a p-type NiO conducting film for organic solar cell, a method for preparation of a NiO conducting film, and an organic solar cell with enhanced power conversion efficiency using the same.

2. Description of the Related Art

In recent years, due to the rise in gas prices, environmental problems, lack of fossil fuel energy, disposal problems of nuclear waste matters and difficulties of locating new power plants, new and renewable energies receive spotlight and researches of clean energy, especially, solar cell have been actively conducted.

Solar cell is a device that converts light energy into electric energy with photovoltaic effect and mainly categorized into silicon solar cell, thin film solar cell, dye-sensitized solar cell, organic polymer solar cells, or the like according to constituting materials. For now, the inorganic silicon solar cell is the most widely used one but its production cost is still high due to the high prices of materials and complicated production line.

Under these circumstances, organic cells are increasingly expected to be a new substitute for solar cells in many researches and developments. Compared to the other solar cells, organic solar cells requires simple production line with cheap production costs due to low unit costs and easy and various processabilities of organic materials. Organic solar cells have achieved 5% of power conversion efficiency and this keeps increasing.

Currently, organic solar cells are produced by the process of coating a mixture of P3HT with high hole mobility and fullerene with high electron mobility onto the ITO substrate which is a transparent conductive substrate. Herein, to achieve the superior power conversion efficiency, it is essential to use a p-type conductive polymer PEDOT:PSS [poly(3,4-ethylenedioxythiophene):poly(4-styrene sulfonate)] as an electric charge collecting layer and lower the resistance of ohmic contact between a photoactive layer and an electrode. The use of polymer-organic blend can provide advantages of convenience, flexibility and economic unit cost and is thus considered to be the future solar cell, mainly based on the benefit of high processibility of the polymer according to which it is possible to fabricate a device by mixing two organic semiconductors in solution and carrying out a simple spin-coating or various printing processes.

Meanwhile, NiO may be used as a replacement of PEDOT:PSS for p-type conducting film of solar cell. When Ni, a ferromagnetic substance, is combined with oxygen, it turns into NiO with an anti-ferromagnetic substance. NiO is expected to have a wide range of applications due to its superior electrical, chemical, magnetic, or optical stability. Especially, noting the anti-ferromagnetic characteristic and wide band gap (3.6˜4.0 eV) of NiO, many researches have been conducted to use NiO as various functional thin films like transient metal oxides semiconductor, transparent conductive oxide, electrochromic thin film, spin valve, etc. Since NiO has wide band gap, it shows high transmittance in the absorbing photoactive layer of organic solar cells. Also, as fermi level (˜5.0 eV) of NiO is almost the same as HOMO Level (˜5.1 eV) of widely-used photoactive layer P3HT resulting in ohmic contact between transparent electrodes ITO (˜4.9 eV), and it is thus possible to fabricate the organic solar cells with enhanced power conversion efficiency.

In order to fabricate a NiO thin film on the substrate using nickel composition, mainly, atomic layer deposition (ALD) and metal organic chemical vapor deposition (MOCVD) may be implemented. In ALD, a thin film is deposited by supplying nickel and oxygen by turns. However, due to the relatively high processing temperature, this method is difficult to apply for the low-melting substrates. Further, ALD has a limitation of corrosion of a reactor due to by-product such as hydrogen chloride. Compared to ALD method, MOCVD, a method of depositing thin film with metal organic of solid or liquid source, has limitations especially to thickness control of thin film, requires a higher processing temperature, and suffers problematic roughness of surface.

Also, in order to grow a n-type zinc oxide film, various coating methods such as sputtering, chemical vapor coating, metal organic chemical vapor coating, molecular beam epitaxy, pulsed laser coating, atomic layer coating, and metal organic molecular beam epitaxy coating are available. However, the above-mentioned methods involve expensive and complicated equipments and drawback of possible damages to the thin film and the substrate if growth requires high temperature.

Accordingly, to solve the above-mentioned problems, we developed a fabrication method of an organic solar cell with improved power conversion efficiency, in which a p-type conducting film is deposited by vacuum sputtering and a n-type conducting film is fabricated by spin-coating a precursor solution in sol-gel phase.

### SUMMARY OF THE INVENTION

Certain exemplary embodiments will now be described in greater detail with reference to the accompanying drawings.

In one embodiment, a p-type NiO conducting film for an organic solar cell is provided.

In another embodiment, a preparation method of the NiO conducting film is provided.

In yet another embodiment, a NiO conducting cell for an organic solar cell with enhanced power conversion efficiency is provided.

According to the embodiment, a p-type NiO conducting layer for an organic solar cell may be prepared by vacuum sputtering under 5 mTorr for 20˜600 seconds in which nickel or nickel oxide is used as a target material, RF power of 100˜300 W is supplied, and argon, oxygen or a mixture of the argon and the oxygen is supplied.

Additionally, according to the preparation method of the NiO conducting layer according to another embodiment, vacuum sputtering may be performed under 5 mTorr for 20˜600 seconds in which nickel or nickel oxide is used as a target material, RF power of 100˜300 W is applied, and argon, oxygen or a mixture of the argon and the oxygen is supplied.

According to yet another embodiment, in the organic solar cell with enhanced power conversion efficiency which may be layered in the order of: a substrate; an anode; a p-type conducting film; a photoactive layer; a cathode, or a substrate; an anode; a p-type conducting film; a photoactive layer; a N-type conducting film; a cathode, or a substrate; an anode; a N-type conducting film; a photoactive layer; a P-type conducting film; cathode, the p-type NiO conducting film may be prepared by vacuum sputtering in which nickel or nickel oxide is used as a target material, RF power of 100˜300 W is supplied, and argon, oxygen or a mixed gas of the oxygen and the argon is supplied.

The p-type NiO conducting film for an organic solar cell may be easily prepared by performing vacuum sputtering, and since the h-type conducting film is deposited by simply coating a precursor solution in sol phase, the organic solar cells having the NiO conducting film has the enhanced power conversion efficiency. Accordingly, the provided inventive concept is efficiently applicable particularly to organic solar cells and organic light emitting devices.

### BRIEF DESCRIPTION OF THE DRAWINGS

The above and; or other aspects of what is described herein will be more apparent by describing certain exemplary embodiments with reference to the accompanying drawings, in which:

FIG. 1 shows an embodiment of an organic solar cell;

FIG. 2 shows an embodiment of an organic solar cell;

FIG. 3 shows an embodiment of an organic solar cell;

FIGS. 4A and 4B are graphical representations of electrical resistivity and optical transmittance according to content of the oxygen in a mixed gas of argon and oxygen, according to a preparing method of a NiO conducting film according to an embodiment;

FIG. 5 is a graphical representation of the relation between short-circuit current and voltage of an organic solar cell prepared by Embodiments 2, 3, 4, 5 and 6 and Comparative example 1; and

FIG. 6 is a graphical representation of the relation between short-circuit current and voltage of an organic solar cell prepared by Embodiment 7 and Comparative example 2.

### DETAILED DESCRIPTION OF EXEMPLARY EMBODIMENTS

Certain exemplary embodiments will now be described in greater detail with reference to the accompanying drawings. The present teaching may be readily applied to other types of apparatuses. Also, the description of the exemplary embodiments of the present invention is intended to be illustrative, and not to limit the scope of the claims, and many alternatives, modifications, and variations will be apparent to those skilled in the art.

In one embodiment, a p-type NiO conducting film of an organic solar cell may be prepared by vacuum sputtering in which nickel or nickel oxide is used as a target material, and argon, oxygen or a mixed gas of the two is supplied.

In fabricating a p-type NiO conducting film for an organic solar cell, the NiO conducting film may be prepared to have a thickness of 1˜30 nm by vacuum sputtering under 5 mTorr for 20˜600 seconds, in which nickel or nickel oxide is used as a target material, RF power of 100˜300 W is applied, and argon, oxygen or a mixture of the two is supplied. If the thickness of the NiO conducting film prepared by the vacuum sputtering process is below 1 nm, the NiO conducting film is too thin to function as a conducting layer, and if the thickness is above 30 nm, the optical transmittance deteriorates.

In fabricating the NiO conducting film, the mixing ratio of argon and oxygen may not be fixed, that is, the mixing ratio is changeable in between 1:99 and 99:1, considering that increasing oxygen ratio enhances electric conductivity but lowers optical transmittance.

In the vacuum sputtering process, the thickness of the NiO conducting film may be regulated to between 1˜30 nm. In sputtering process, a target material generally including the same material as that of the target layer is used, and reactive gas like oxygen and nitrogen is used to form a metal oxide or nitrogen thin layer. The sputtering is particularly effective when a precise thickness control is necessary. According to sputtering process, inactive element like argon is collided against the metal substrate, causing metal molecules to scatter so that a thin layer is attached to the surface. When inactive gas as sputtering gas is flowed into a vacuum chamber and direct or alternate current is applied to the target, plasma is generated between the depositing substrate and the target. Within the plasma, inactive gas is ionized into a positive ion by high power DC Ammeter. The positive ion of the inactive gas is accelerated into cathode by DC Ammeter and collided against the surface of the target materials. From the clashed target materials, atoms are ejected from the surface due to exchange of momentum by the perfectly elastic collision. As explained above, when ion is collided with the greater momentum than binding energy, atoms between lattice of materials are pushed due to the ion clash, and expelled from the surface.

In one embodiment, a preparation method of NiO conducting film with thickness between 1˜30 nm may be provided by vacuum sputtering under processing pressure of 5 mTorr for 20˜600 seconds, in which RF power is applied in a range of 100˜300 W, and argon, oxygen or the mixed gas of the two is supplied.

According to one embodiment, in an organic solar cell with enhanced power conversion efficiency, which is layered in the order of: a substrate; an anode; a p-type conducting film; a photoactive layer; and a cathode, the p-type conducting film may be a NiO conducting film which may be prepared by vacuum sputtering in which nickel or nickel oxide is used as a target material, and argon, oxygen or the mixed gas of the two is supplied.

The NiO conducting film may be prepared by performing vacuum sputtering under processing pressure of 5 mTorr for 20˜600 seconds, wherein nickel or nickel oxide may be used as a target material, RF power is applied in a range of 100˜300 W, and argon, oxygen or the mixed gas of the two is supplied. Herein, the mixing ratio of argon and oxygen may not be fixed, i.e., the mixing ratio is changeable in between 1:99 and 99:1, considering that increasing oxygen ratio enhances electric conductivity but lowers optical transmittance.

The substrate may be a flexible polymer substrate selected from the group consisting of polyethyleneterephthalate (PET), polyethylene naphthalate (PEN), polyethylene (PE), polyethersulfone (PES), polycarbonate (PC), polyarylate (PAT) and polyimide (PI), or steel use stainless (SUS), aluminum, steel, copper, or glass substrates. Also, the anode may use indium-tin-oxide (ITO), indium-zinc-oxide (IZO), indium-zinc-tin-oxide (IZTO), aluminum-zinc-oxide (AZO), indium-tin-oxide-Ag-indium-tin-oxide (ITO-Ag-ITO), indium-zinc oxide-Ag-indium-zinc-oxide (IZO-Ag-IZO), indium-zinc-tin-oxide-Ag-indium-zinc-tin-oxide (IZTO-Ag-IZTO), aluminum-zinc-oxide-Ag-aluminum-zinc-oxide (AZO-Ag-AZO), or a mixture of the two or more.

With respect to the photoactive layer, a bi-continuous phase interpenetrating network type polymer composite membrane with effective movement of electric charges may be fabricated by mixing electron donor and electron acceptor appropriately, and then spin-coating and thermally-treating the mixture. The organic solar cell according to one embodiment may include, as the electron donor, polythiophen derivative, poly(para-phenylene) derivative, poly fullerene derivative, poly acetylene derivative, polypyrrole derivative, poly vinylcarbazole derivative, polyaniline derivative and poly phenylenevinylene derivative, and may include as the electron acceptor, organic electron affinity materials including fullerene (C60 fullerene and C70 fullerene) and 3, 4, 9, 10-perylenetetracarboxylic bisbenximidazole (PTCBI), and derivatives thereof.

The cathode may utilize a lithium fluoride and aluminum (LiF/Al) layer, a calcium and aluminum (Ca/Al) layer, a calcium and silver (Ca/Ag) layer, a magnesium and silver (Mg/Ag) layer, or aluminum (Al), silver (Ag), gold (Au), or copper (Cu), or a mixture of two or more of the above.

According to one embodiment, in an organic solar cell with enhanced power conversion efficiency, which may be layered in the order of: a substrate: an anode; a p-type conducting film; a photoactive layer; a n-type conducting film; a cathode, the p-type NiO conducting film may be prepared by vacuum sputtering in which nickel or nickel oxide is used as a target material, and argon, oxygen or the mixed gas of the two is supplied.

The NiO conducting film may be prepared by vacuum sputtering under processing pressure of 5 mTorr for 20˜600 seconds, in which nickel or nickel oxide may be used as a target material, RF power is applied in a range of 100˜300 W, and argon, oxygen or the mixed gas of the two is supplied. Herein, the mixing ratio of argon and oxygen may not be fixed, that is, the mixing ratio is changeable in between 1:99 and 99:1, considering that increasing oxygen ratio enhances electric conductivity but lowers optical transmittance.

The substrate may be a flexible polymer substrate selected from the group consisting of: polyethyleneterephthalate (PET); polyethylene naphthalate (PEN); polyethylene (PE); polyethersulfone (PES); polycarbonate (PC); polyarylate (PAT); and polyimide (PI), or steel use stainless (SUS), aluminum, steel, copper, or glass substrate. Additionally, the anode may use indium-tin-oxide (ITO), indium-zinc-oxide (IZO), indium-zinc-tin-oxide (IZTO), aluminum-zinc-oxide (AZO), indium-tin-oxide-Ag-indium-tin-oxide (ITO-Ag-ITO), indium-zinc-oxide-Ag-indium-zinc-oxide (IZO-Ag-IZO), indium-zinc-tin-oxide-Ag-indium-zinc-tin-oxide (IZTO-Ag-IZTO), and aluminum-zinc-oxide-Ag-aluminum-zinc-oxide (AZO-Ag-AZO), or a mixture of two or more of the above.

The n-type conducting film may utilize ZnO, TiO₂, or Cs₂CO₃. The ZnO conducting film may be fabricated in a manner in which a mixture of zinc acetate, 2-methoxyethanol, and ethanolamine is spin-coated at 500˜5000 rpm, and thermally-treated at 100˜250° C. under atmospheric condition for 1˜30 minutes. The thickness of ZnO conducting film may range between 10˜200 nm. If the thickness of ZnO conducting film is below 10 nm, electrical resistivity is increased, and if the thickness is above 200 nm, transmittance is decreased. The titanium oxide conducting film may be prepared in a manner in which a mixture of titanium isopropoxide (Ti[OCH(CH₃)₂]₄), 2-methoxyethanol and ethanolamine is spin-coated at 500˜5000 rpm, and thermally treated under atmospheric condition at 80˜250° C. for 1˜120 minutes. Additionally, the cesium carbonate (Cs₂CO₃) conducting film may be prepared in a manner in which a mixture of cesium carbonate (Cs₂CO₃) and 2-methoxyethanol is spin-coated at 500˜5000 rpm and thermally treated under atmospheric condition at 100˜200° C. for 1˜30 minutes.

With respect to the photoactive layer, a bi-continuous phase interpenetrating network type polymer composite membrane with effective movement of electric charges may be fabricated by mixing electron donor and electron acceptor appropriately, and then spin-coating and thermally-treating the mixture. The organic solar cell according to one embodiment may include, as the electron donor, polythiophen derivative, poly(para-phenylene) derivative, poly fullerene derivative, poly acetylene derivative, polypyrrole derivative, poly vinylcarbazole derivative, polyaniline derivative and poly phenylenevinylene derivative, and include, as the electron acceptor, organic electron affinity materials including fullerene (C60 fullerene and C70 fullerene) and 3, 4, 9, 10-perylenetetracarboxylic bisbenximidazole (PTCBI), and derivatives thereof.

The cathode may utilize a lithium fluoride and aluminum (LiF/Al) layer, a calcium and aluminum (Ca/Al) layer, a calcium and silver (Ca/Ag) layer, a magnesium and silver (Mg/Ag) layer, or aluminum (Al), silver (Ag), gold (Au), or copper (Cu), or a mixture of two or more of the above.

According to one embodiment, in an organic solar cell with enhanced power conversion efficiency, which may be layered in the order of: a substrate; an anode; a n-type conducting film; a photoactive layer; a p-type conducting layer; and a cathode, the p-type conducting film may be prepared by vacuum sputtering in which nickel or nickel oxide is used as a target material, and argon, oxygen or the mixed gas of the two is supplied.

The present inventive technical concept will be explained in greater detail below based on the exemplary embodiments which are not to be construed as limiting the present inventive concept.

### Embodiment 1

### Preparation of a P-Type NiO Conducting Film for an Organic Solar Cell

Substrate was coated with indium tin oxide (ITO) and ultra-sonic washed with the addition of acetone for 10 minutes and then washed with ozonator for 10 minutes. On the surface of the ITO coating, a 50 nm-thick NiO conducting film was deposited by vacuum sputtering under processing pressure of 5 mTorr for 60 seconds in which nickel or nickel oxide was used as a target material, 50 sccm of a mixed gas of argon and oxygen was supplied, and RF power as 100 W was applied.

### Embodiment 2

### Preparation 1 of an Organic Solar Cell

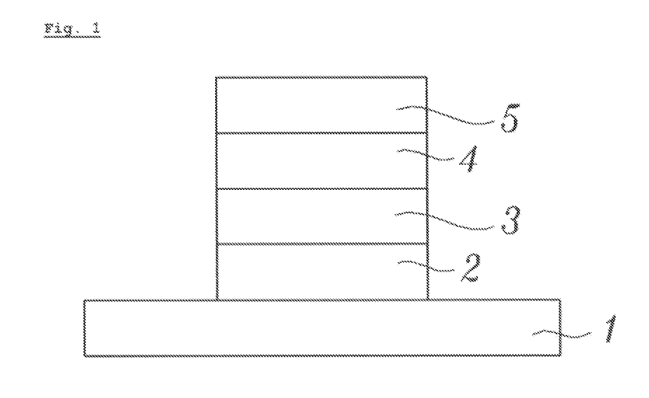

Substrate was coated with indium tin oxide (ITO) and ultra-sonic washed with the addition of acetone for 10 minutes and then washed with ozonator for 10 minutes. On the surface of the ITO coating, a 3 nm-thick NiO conducting film was deposited by vacuum sputtering under 5 mTorr for 60 seconds in which nickel or nickel oxide was used as a target material, and 50 sccm of oxygen was supplied. A photoactive layer 200 nm in thickness was deposited on the NiO conducting film, by mixing 20 mg of P3HT (poly(3-hexylthiophene)) and 20 mg of PCBM, as photoactive substances, with 1 ml of dichlorobenzene solution to prepare a photoactive layer solution, and spin-coating the solution at 600 rpm. The thin film was then thermally treated at 150° C. for 20 minutes using glove box, and a LiF/Al cathode (LiF/AI) was prepared in a manner of depositing the LiF to a thickness of 1.0˜1.5 nm using thermal evaporator for 0.1 A/sec, and aluminum was deposited to a thickness of 150˜200 nm for 5˜10 A/sec. As a result, an organic solar cell was prepared. (see FIG. 1)

### Embodiment 3

### Preparation 2 of an Organic Solar Cell

Except for the fact that the NiO conducting film 5 nm in thickness was deposited by the vacuum sputtering for 100 seconds, the rest of the process of preparing an organic solar cell is the same as that of Embodiment 2.

### Embodiment 4

### Preparation 3 of an Organic Solar Cell

Except for the fact that the NiO conducting film 10 nm in thickness was deposited by the vacuum sputtering for 200 seconds, the rest of the process of preparing an organic solar cell is the same as that of Embodiment 2.

### Embodiment 5

### Preparation 4 of an Organic Solar Cell

Except for the fact that the NiO conducting film 20 nm in thickness was deposited by the vacuum sputtering for 400 seconds, the rest of the process of preparing an organic solar cell is the same as that of Embodiment 2.

### Embodiment 6

### Preparation 5 of an Organic Solar Cell

Except for the fact that the NiO conducting film 30 nm in thickness was deposited by the vacuum sputtering for 600 seconds, the rest of the process of preparing an organic solar cell is the same as that of Embodiment 2.

### Embodiment 7

### Preparation 6 of an Organic Solar Cell

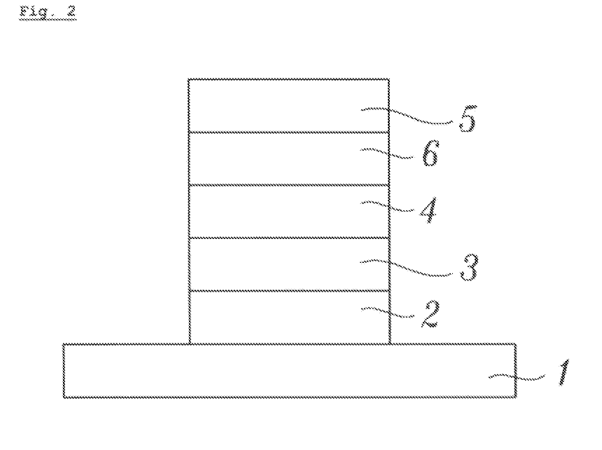

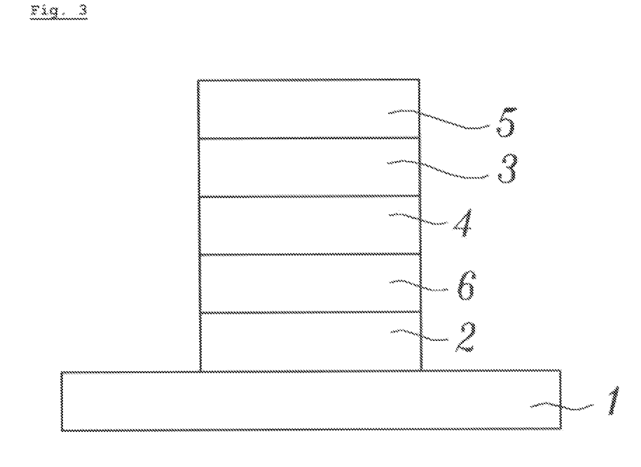

Substrate was coated with indium tin oxide (ITO) and ultra-sonic washed with the addition of acetone for 10 minutes and then washed with ozonator for 10 minutes. On the surface of the ITO coating, a 3 nm-thick NiO conducting film was deposited by vacuum sputtering under 5 mTorr for 60 seconds, in which nickel or nickel oxide was used as a target material, and 50 sccm of oxygen was supplied. A photoactive layer 200 nm in thickness was deposited on the NiO conducting film, by mixing 20 mg of P3HT (poly(3-hexylthiophene)) and 20 mg of PCBM, as the photoactive substances, with 1 ml of dichlorobenzene solution to form photoactive layer solution and spin-coating the solution at 600 rpm. The thin film was then thermally treated at 150° C. for 20 minutes using glove box. 0.3 mol solution of ZnO was spin-coated with zinc acetate (Aldrich, as precursor), 2-methoxyethanol (Aldrich, as solvent), ethanolamine (Aldrich, as excipient) at 2000˜3000 rpm to form a thin film which was 10˜50 nm in thickness. The thin film was thermally treated under atmospheric condition at 100˜200° C. for 1020 minutes. On the surface of the ZnO conducting film, a cathode was deposited to a thickness of 150˜200 nm by using LiF/Al or Ag with thermal evaporator. As a result, an organic solar cell was prepared. (see FIGS. 2 and 3)

The processing time of vacuum sputtering of an organic solar cell and the thickness of the NiO conducting film prepared by Embodiments 2˜6 are listed in Table 1 below.

TABLE 1

| | Processing time of | Thickness of NiO |
|---|---|---|
| Example | vacuum sputtering (sec) | conducting film (nm) |
| Embodiment 2 | 60 | 3 |
| Embodiment 3 | 100 | 5 |
| Embodiment 4 | 200 | 10 |
| Embodiment 5 | 400 | 20 |
| Embodiment 6 | 600 | 30 |

### Comparative Example 1

### Preparation 7 of an Organic Solar Cell

The p-type conducting film (PEDOT) 40 nm in thickness, which was prepared by mixing 1 ml of conductive polymer PEDOT:PSS (Baytron P) with 2 ml of isopropyl alcohol, filtering the mixture with syringe filter, and spin-coating the resultant matter at 5000 rpm and drying at 150° C. for 1 minute, was used. Except for using the PEDOT prepared in the abovementioned manner, the rest of the process for fabricating an organic solar cell is the same as that of Embodiment 2.

### Comparative Example 2

### Preparation 8 of Organic Solar Cell

The p-type conducting film (PEDOT) 40 nm in thickness, which was prepared by mixing 1 ml of conductive polymer PEDOT:PSS (Baytron P) with 2 ml of isopropyl alcohol (IPA), filtering the mixture with syringe filter of diameter filter size, and spin coating the resultant matter at 5000 rpm and drying at 150° C. for 1 minute, was used. Except for using the PEDOT, the rest of the process for fabricating an organic solar cell is the same as that of Embodiment 7.

### <Analysis of Electric Conductivity and Optical Transmittance of a NiO Thin Film According to the Ratio of Mixed Gas of Argon and Oxygen>

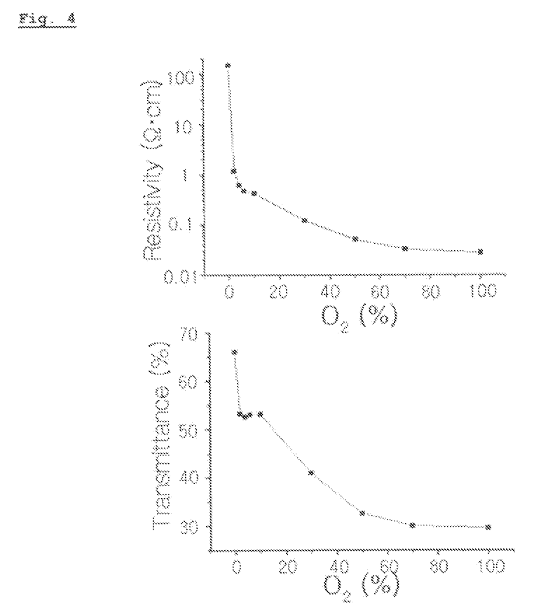

To analyze the electric conductivity and optical transmittance of a NiO thin film according to the mixing ratio of argon and oxygen, electric conductivity and optical transmittance of NiO thin film were measured, with varying the ratio of oxygen in between 0 and 100%. The result is represented in FIG. 4.

By varying the conditions of sputtering process, the electric conductivity and optical transmittance of NiO thin film prepared by the embodiment were easily controlled.

FIGS. 4A and 4B are graphical representations of electrical resistivity and optical transmittance according to content of the oxygen in a mixed gas of argon and oxygen. Referring to FIG. 4A, when the composition of a NiO thin film was almost at the stoichiometric ratio (i.e., oxygen 0%), a relatively large amount of electrical resistivity appeared, and when the ratio of oxygen increased in the NiO thin film, the electrical conductivity increased. When the ratio of oxygen was above 50%, electrical resistivity was below 0.1 Ω·cm, exhibiting relatively good conductivity. The p-type conductivity was also confirmed by van der Pauw method. Also, in FIG. 4B, when the ratio of oxygen increased, the optical transmittance of a NiO thin film decreased. It is because if oxygen exists in the thin film in an excessive amount, Ni atom exists as 3⁺ instead of 2⁺, and Ni³⁺ ion acts as color center which causes light absorption. Given the above, it is therefore necessary that the p-type NiO conducting film applicable for organic solar cell requires optimal thickness and proper control of a characteristic because the NiO conducting film has to carry out the hole transfer and also exists on a path in a cell structure where the light is transmitted through the substrate.

### Experiment 1

### Property Evaluation 1 of an Organic Solar Cell

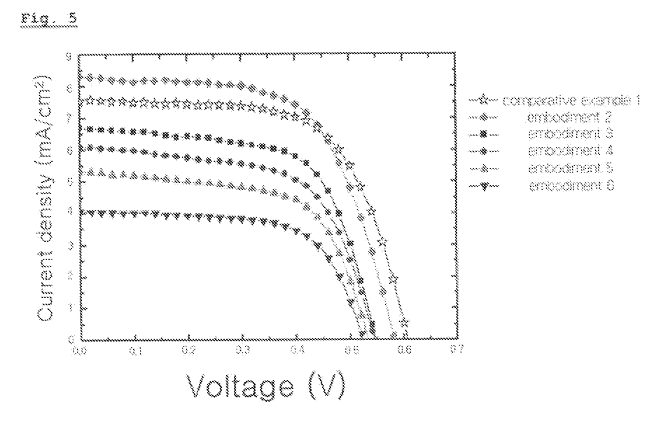

To evaluate the property of organic solar cells prepared according to Embodiments 2, 3, 4, 5 and 6, the short-circuit current, open circuit voltage, fill factor and power conversion efficiency were measured and summarized as shown in FIG. 5 and Table 2.

The voltage (V) and current (I) was measured at 25° C., using solar simulator (Pecell Technologies Inc., PEC-L11), to measure the short-circuit current, open circuit voltage, fill factor and power conversion efficiency.

TABLE 2

| | Short-circuit | | | Power |
|---|---|---|---|---|
| | current | Open circuit | Fill | conversion |
| Example | (mA/cm²) | (V) | factor | efficiency (%) |
| Comparative | 7.55 | 0.60 | 0.64 | 2.90 |
| example 1 | | | | |
| Embodiment 2 | 8.30 | 0.58 | 0.63 | 3.01 |
| Embodiment 3 | 6.71 | 0.54 | 0.64 | 2.34 |
| Embodiment 4 | 6.10 | 0.54 | 0.62 | 2.04 |
| Embodiment 5 | 5.35 | 0.54 | 0.61 | 1.77 |
| Embodiment 6 | 4.06 | 0.52 | 0.65 | 1.38 |

Referring to FIG. 5 and Table 2, when the thickness of NiO was changed from 30 nm to 3 nm, although there was no noticeable change in the fill factor, the open-circuit increased from 0.52V to 0.58V, short-circuit current increased from 4.06 mA/cm² to 8.30 mA/cm², and the power conversion efficiency increased from 1.38% to 3.01%. Compared to Comparative 1 in which PEDOT:PSS was used as a p-type conducting film, the open circuit was slightly decreased from 0.6V to 0.58V, and the short-circuit current was greatly increased from 7.55 mA/cm² to 8.30 mA/cm², so the power conversion efficiency was increased from 2.90% to 3.01%. Therefore, it is proven that using a p-type nickel oxide conducting film rather than PEDOT:PSS brings in superior properties of the organic solar cell.

### Experiment 2

### Property Evaluation 2 of an Organic Solar Cell

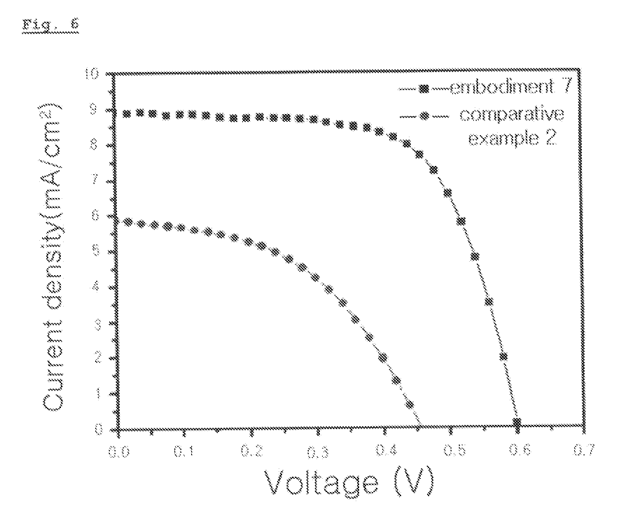

To evaluate the properties of the organic solar cells prepared according to Embodiment 7 and Comparative example 2, the short-circuit current, open circuit voltage, fill factor and power conversion efficiency were measured and summarized as shown in FIG. 6 and Table 3.

The voltage (V) and current (I) at 25° C. were measured, using solar simulator (Pecell Technologies Inc., PEC-L11), to measure the short-circuit current, open circuit voltage, fill factor and power conversion efficiency.

TABLE 3

| | short-circuit | | | Power |
|---|---|---|---|---|
| | current | open circuit | fill | conversion |
| Example | (mA/cm²) | (V) | factor | efficiency (%) |
| Embodiment 7 | 8.87 | 0.6 | 0.65 | 3.51 |
| Comparative | 5.86 | 0.47 | 0.47 | 1.26 |
| example 2 | | | | |

Referring to FIG. 6 and Table 3, the short-circuit current of the organic solar cell prepared by Embodiment 7 was 8.87 mA/cm² and the short-circuit current of the organic solar cell prepared by Comparative example 2 was 5.86 mA/cm², indicating that power conversion efficiency of Embodiment 7 (3.51%) was higher than that of Comparative example 2 (1.26%). The p-type nickel oxide conducting film and n-type zinc oxide conducting film were used to fabricate an organic solar cell layered in the order of p-type/photoactive layer/n-type, which showed 3.51% of high power conversion efficiency. This is higher than 1.26% efficiency of Comparative example 2 in which PETDOT:PSS was used as a p-type conducting film, and than 3.01% efficiency of Comparative example 1 which did not include the n-type zinc oxide conducting film.

The foregoing exemplary embodiments and advantages are merely exemplary and are not to be construed as limiting the present inventive concept. The present teaching may be readily applied to other types of apparatuses. Also, the description of the exemplary embodiments of the present invention is intended to be illustrative, and not to limit the scope of the claims, and many alternatives, modifications, and variations will be apparent to those skilled in the art.

Although the present invention has been described with reference to preferred embodiments, workers skilled in the art will recognize that changes may be made in form and detail without departing from the spirit and scope of the invention.

What is claimed is:

1. A P-type NiO conducting film for an organic solar cell prepared by vacuum sputtering, in which nickel or nickel oxide is used as a target material and oxygen, argon or a mixed gas of the oxygen and the argon is supplied.

2. The p-type NiO conducting film of claim 1, wherein RF power is applied in a range of 100-300 W, the argon, oxygen or the mixed gas of the argon and the oxygen is supplied, and the vacuum sputtering is carried out under 5 mTorr for 20˜600 seconds.

3. The p-type NiO conducting film of claim 1, wherein the NiO conducting film by the vacuum sputtering has a thickness in a range of 1˜30 nm.

4. A preparation method of a NiO conducting film, in which the NiO conducting film is formed to have a thickness in a range of 1˜30 nm by vacuum sputtering under pressure of 5 mTorr for 20˜600 seconds in which RF power is applied in a range of 100-300 W, and argon, oxygen or a mixed gas of the argon and the oxygen is supplied.

5. An organic solar cell layered in the order of:
a substrate;
an anode;
a p-type conducting film;
a photoactive layer; and
a cathode, the organic solar cell having enhanced power conversion efficiency, wherein the p-type NiO conducting film is prepared by vacuum sputtering in which nickel or nickel oxide is used as a target material, and argon, oxygen or a mixed gas of the oxygen and the argon is provided.

6. An organic solar cell layered in the order of:
a substrate;
an anode;
a p-type conducting film; a photoactive layer;
a n-type conducting film; and
a cathode, the organic solar cell having enhanced power conversion efficiency, wherein the p-type conducting film is prepared by vacuum sputtering in which nickel or nickel oxide is used as a target material, and argon, oxygen or a mixed gas of the oxygen and the argon is supplied.

7. The organic solar cell of claim 6, wherein the n-type conducting film may be a zinc oxide (ZnO), titanium oxide (TiO₂) or cesium carbonate (Cs₂CO₃) conducting film.

8. The organic solar cell of claim 7, wherein the zinc oxide conducting film is prepared to have a thickness in a range of 10˜200 nm in a manner in which a mixed solution of zinc acetate, 2-methoxyethanol and ethanolamine is spin-coated at 500˜5000 rpm and thermally-treated at 100˜250° C. for 1˜30 minutes.

9. The organic solar cell of claim 7, wherein the titanium oxide conducting film is fabricated in a manner in which a mixed solution of titanium isopropoxide(Ti[OCH(CH₃)₂]₄), 2-methoxyethanol and ethanolamine is spin-coated at 500˜5000 rpm and thermally treated under atmospheric condition at 80˜250° C. for 1˜120 minutes.

10. The organic solar cell of claim 7, wherein the cesium carbonate conducting film is fabricated in a manner in which a mixed solution of cesium carbonate (Cs₂CO₃) and 2-methoxyethanol is spin-coated under atmospheric condition at 500˜5000 rpm and thermally treated at 100˜200° C. for 1˜30 minutes.

11. An organic solar cell layered in the order of:
a substrate;
an anode;
a N-type conducting film;
a photoactive layer;
a p-type conducting film; and
a cathode, the organic solar cell having enhanced power conversion efficiency, wherein the p-type conducting film is fabricated by vacuum sputtering in which nickel or nickel oxide is used as a target material, and argon, oxygen or a mixed gas of the argon and the oxygen is supplied.

12. The organic solar cell of claim 11, wherein the n-type conducting film may be a zinc oxide (ZnO), titanium oxide (TiO₂) or cesium carbonate (Cs₂CO₃) conducting film.

13. The organic solar cell of claim 12, wherein the zinc oxide conducting film is prepared to have a thickness in a range of 10˜200 nm in a manner in which a mixed solution of zinc acetate, 2-methoxyethanol and ethanolamine is spin-coated at 500˜5000 rpm and thermally-treated under atmospheric condition at 100˜250° C. for 1˜30 minutes.

14. The organic solar cell of claim 12, wherein the titanium oxide conducting film is fabricated in a manner in which a mixed solution of titanium isopropoxide(Ti[OCH(CH₃)₂]₄), 2-methoxyethanol and ethanolamine is spin-coated at 500˜5000 rpm and thermally treated under atmospheric condition at 80˜250° C. for 1˜120 minutes.

15. The organic solar cell of claim 12, wherein the cesium carbonate conducting film is fabricated in a manner in which a mixed solution of cesium carbonate (Cs₂CO₃) and 2-methoxyethanol is spin-coated under atmospheric condition at 500˜5000 rpm and thermally treated at 100˜200° C. for 1˜30 minutes.
